(19) United States
(12) Patent Application Publication
(10) Pub. No.: US 2016/0355534 A1
(43) Pub. Date: Dec. 8, 2016

(54) IRIDIUM (III) BASED PHOSPHORS BEARING PINCER CARBENE AND PYRAZOLYL CHELATES

(71) Applicant: National Tsing Hua University, Hsinchu (TW)

(72) Inventors: Yun Chi, Hsinchu (TW); Bihai Tong, Ma'anshan (CN); I-Jen Chen, Pingtung (TW); Chu-Yun Kuei, New Taipei City (TW)

(21) Appl. No.: 14/806,801

(22) Filed: Jul. 23, 2015

(30) Foreign Application Priority Data
Jun. 5, 2015 (TW) 104118339

(51) Int. Cl. C07F 15/00; H01L 51/00; C09K 11/06

(52) U.S. Cl. CPC C07F 15/0033; C09K 11/06; H01L 51/0085; C09K 2211/185

(57) ABSTRACT

The present invention provides a class of iridium (III) based phosphors bearing both pincer carbene and pyrazolyl chelates. Differing from the conventional cyclometalated Ir(III) metal complexes, these novel phosphorescent Ir(III) metal complexes are synthesized from a class of pincer carbene chelate, a class of pyrazolyl-based chelate and an iridium metal source complex. Because the phosphorescent Ir(III) metal complex proposed by the present invention includes multiple strong bonding interactions (Ir—C bond), the non-radiative decay from the higher lying triplet excited state can be effectively suppressed. Thus, this novel phosphorescent Ir(III) metal complex is able to emit a range of visible light (particularly the blue light) with high color purity and high efficiency as neat sample. Moreover, this novel phosphorescent Ir(III) metal complex is also adapted as the guest emitter in the light emitting layer (EML) for the traditional doped OLED architecture.

### BACKGROUND OF THE INVENTION

### 1. Field of the Invention

The present invention relates to the technology of organic emitting materials, and particularly to the novel phosphorescent emitters, wherein the said phosphorescent emitters belong to a class of iridium (III) based phosphor bearing both pincer carbene and pyrazolyl chelates.

### 2. Description of the Prior Art

It is well known that organic light emitting diode (OLED) device was initially invented and proposed by Eastman Kodak through a vacuum evaporation method. Tang and VanSlyke from Kodak deposited a multilayer architecture of organic semiconducting materials, such as diimine, light emitting material and Alq₃ on a transparent indium tin oxide (abbreviated as ITO) conducting glass to form the hole transporting layer (HTL), light emitting layer (EML) and electron transporting layer (ETL), and subsequently completed the fabrication of an organic electroluminescent (EL) device by depositing a metal electrode on top of the Alq₃ layer. Thereafter, the respective EL devices become the new generation of lighting device for flat panel displays or solid state luminaires because of the high brightness, fast response time, light weight, compactness, true color, no difference in viewing angles, without the need for LCD backlighting plates, and low power consumption.

One important factor that controlled the luminescence efficiency of OLEDs is the light-emitting material. It has been proposed that the emission is produced from the excitons derived from the recombination of electrons and holes in the light-emitting layer (material) of OLED devices. According to electron spin statistics, the ratio of the triplet versus the singlet excitons is approx. 3:1. So that, when a fluorescent material is used as the light-emitting layer of OLED, only the 25% of the singlet excitons can be used to generate the luminescence, while the rest of 75% of triplet excitons are lost through the non-radiative processes. For this reason, the general fluorescent material would produce a maximum internal quantum efficiency of 25%, which amounts to an external quantum efficiency of only 5% in the OLED device.

Cyclometalated Ir(III) metal complexes, such as red emitting Ir(btp)₂(acac) (i.e., bis(2-(2′-benzothienyl)-pyridinato-N,C3′)iridium(acetylacetonate)), green emitting Ir(ppy)₃ (i.e., fac-tris(2-phenylpyridine)iridium(III)), and blue emitting Firpic (i.e., bis[2-(4,6-difluorophenyl)pyridinato-C2,N](picolinato)iridium(III)]), belong to a class of phosphorescent emitters. The chemical structures of the aforementioned Ir(btp)₂(acac), Ir(ppy)₃ and Firpic are represented by the chemical formulas I′, II′ and III′ showed below:

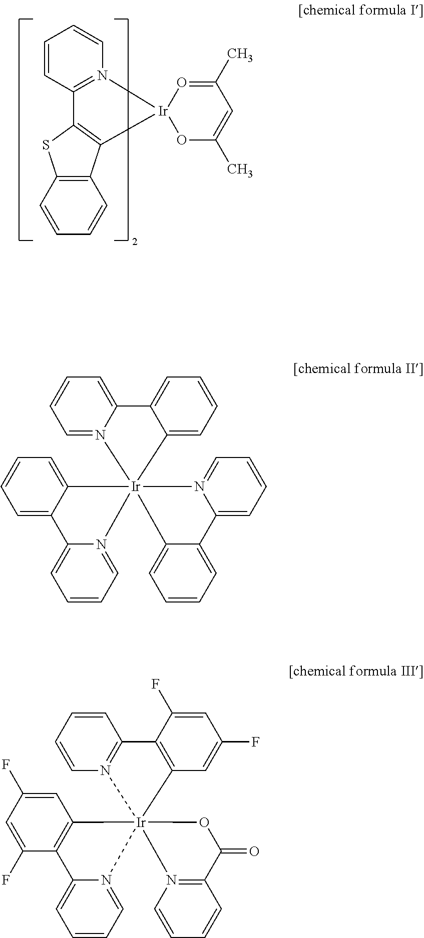

In 2006, Andrew et al. reported a research paper entitled “Luminescent Complexes of Iridium (III) Containing N̂ĈN-Coordinating Tridentate Ligands”, in which an iridium (III) metal complex bearing tridentate N̂ĈN-coordinating chelate has been proposed to be a potentially useful phosphorescent emitter for fabrication of OLEDs and associated optoelectronic devices. These Ir(III) metal complexes are named as Ir(dpyx)(dppy) and Ir(dpyx)(F₄dppy), wherein their chemical structures are represented by following chemical formulas IV′ and V′, respectively.

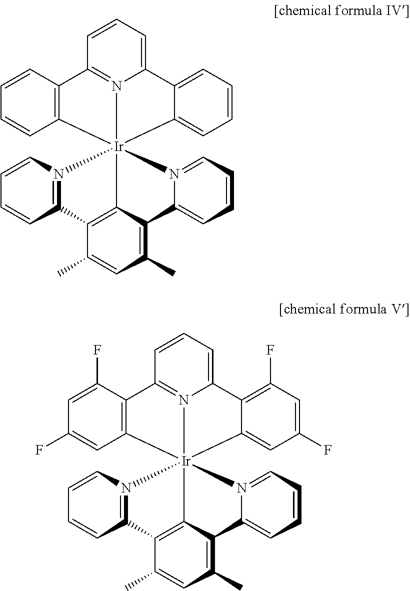

However, these cyclometalated Ir(III) metal complexes reveal three important drawbacks when used as emitters in fabrication of OLEDs: e.g. poor luminescence efficiency, non-tunable color hue, and low synthetic yield (37% and 21%, respectively). Therefore, the person skilled in OLED art is able to assume that, these cyclometalated Ir(III) metal complexes cannot be produced in larger quantity because of the higher manufacturing cost, and cannot be served as the suitable light-emitting material due to the practical difficulty in changing the color hue. Moreover, since the pyridine ligand in the aforesaid cyclometalated Ir(III) metal complex linked to the central metal atom through two terminal Ir—N coordination bonds, the associated bond energy is not enough to induce a strong crystal field for destabilizing the metal-centered dd excited state, which usually served as the quenching state that can effectively reduce the emission quantum yield. For this reason, the cyclometalated Ir(III) metal complex cannot afford suitable stability and luminescence efficiency.

Moreover, it is notable that, the emitters at the lowest energy excited states in an organic light-emitting material are capable to be promoted to the higher lying metal-centered dd excited state by thermal population. As a result, the excitons at the metal-centered dd excited state may possess longer emission lifetime and have higher tendency for undergoing non-radiative deactivation, resulting a significantly reduced emission quantum yield. Such an observation is particularly notable for the typical blue or true-blue emitting phosphorescent materials.

Therefore, according to above descriptions, the person skilled in the art of OLED fabrication and material design are able to know that the conventional cyclometalated Ir(III) metal complexes and/or the common blue-emitting materials have the following drawbacks and shortcoming: (1) the crystal field of the iridium (III) metal complex is not strong enough to warrant a relatively higher lying metal centered dd excited state; (2) the physical stability of the metal complex is inadequate; (3) the non-radiative decay in the blue-emitting material cannot be effectively reduced; and (4) the quantum yield of the blue organic light-emitting material is too low.

Accordingly, in view of the conventional cyclometalated Ir(III) metal complexes and the commercial blue light-emitting materials still include many drawbacks, the inventor of the present application has made great efforts on research thereon and eventually provided a series of iridium (III) based phosphors bearing pincer carbene and pyrazolyl chelates, which are novel phosphorescent emitters capable of serving as excellent dopant emitters in OLEDs.

### SUMMARY OF THE INVENTION

The primary objective of the present invention is to provide a series of iridium (III) based phosphor bearing tridentate pincer carbene and pyrazolyl chelates, They are novel phosphorescent Ir(III) metal complex capable of serving as excellent OLED emitters. Differing from the conventional cyclometalated Ir(III) metal complexes (chemical formula IV′ and V′), this novel phosphorescent Ir(III) metal complex is synthesized from a functionalized pincer carbene chelate, a class of pyrazolyl-based chelate and an iridium (III) metal ion. Since the phosphorescent Ir(III) metal complexes proposed by the present invention possess several strong coordination bonds between ligand and metal atom (both Ir—C and Ir—N bonds), the non-radiative decay originated from the higher lying metal centered dd excited state can be effectively suppressed. Thus, this class of phosphorescent Ir(III) metal complex is capable of giving emission across the whole visible region (from blue to red) with high color purity and high emitting efficiency. Moreover, this class of novel phosphorescent Ir(III) metal complexes is also adapted for being doped in an host light-emitting layer of OLED, so as to be a guest emitter opposite to the host light-emitting layer.

Accordingly, in order to achieve the primary objective of present invention, the inventor of the present invention provides an iridium (III) based phosphor bearing both pincer carbene and pyrazolyl chelates, wherein the said iridium (III) based phosphor bearing both pincer carbene and pyrazolyl chelates is a phosphorescent Ir(III) metal complex, and the said phosphorescent Ir(III) metal complex is synthesized using a dicarbene chelate, a pyrazolyl-based chelate and an iridium metal source complex as starting materials for carrying out chemical synthesis.

According to one embodiment of the iridium (III) based phosphor bearing both pincer carbene and pyrazolyl chelates, wherein the said phosphorescent Ir(III) metal complex is represented by following chemical formulas I, II, III, IV, V, VI, VII, VIII, and IX:

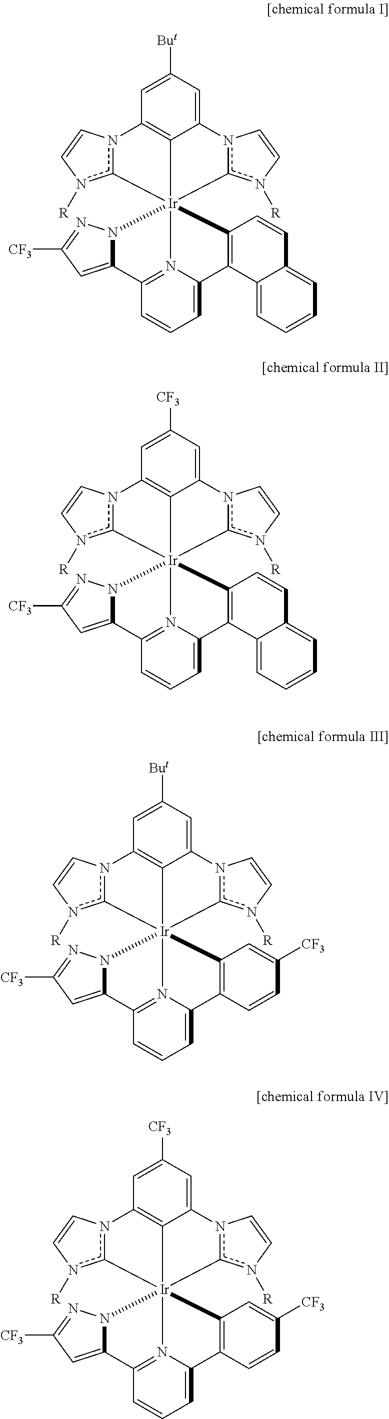

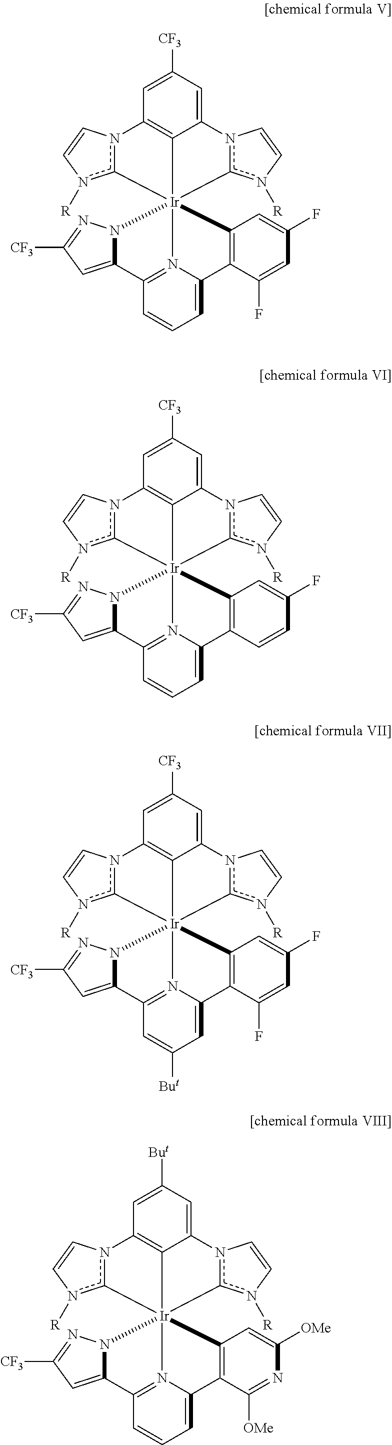

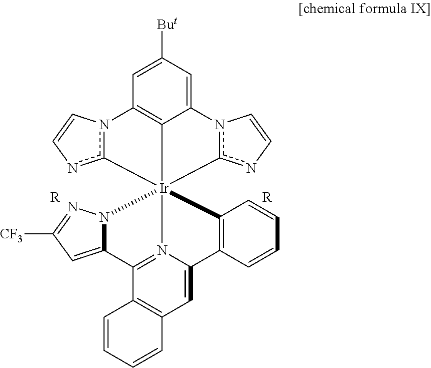

According to one embodiment of the iridium (III) based phosphor bearing pincer carbene and pyrazolyl chelates, wherein the dicarbene chelate is synthesized from following pro-chelates with chemical formulas L1 and L2; moreover, R in chemical formulas L1 and L2 is an aliphatic molecular group represented by isopropyl (i-Pr).

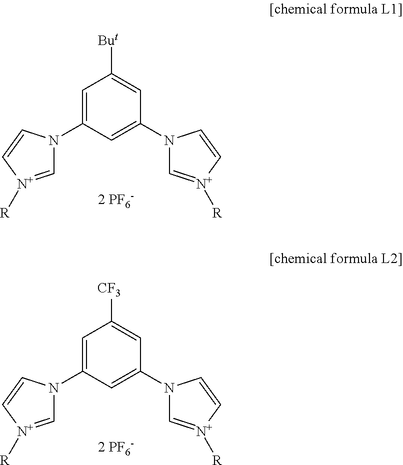

According to one embodiment of the iridium (III) based phosphor bearing pincer carbene and pyrazolyl chelates, wherein the pyrazolyl-based chelate is synthesized from following chelates with chemical formulas L3, L4, L5, L6, L7, L8, and L9.

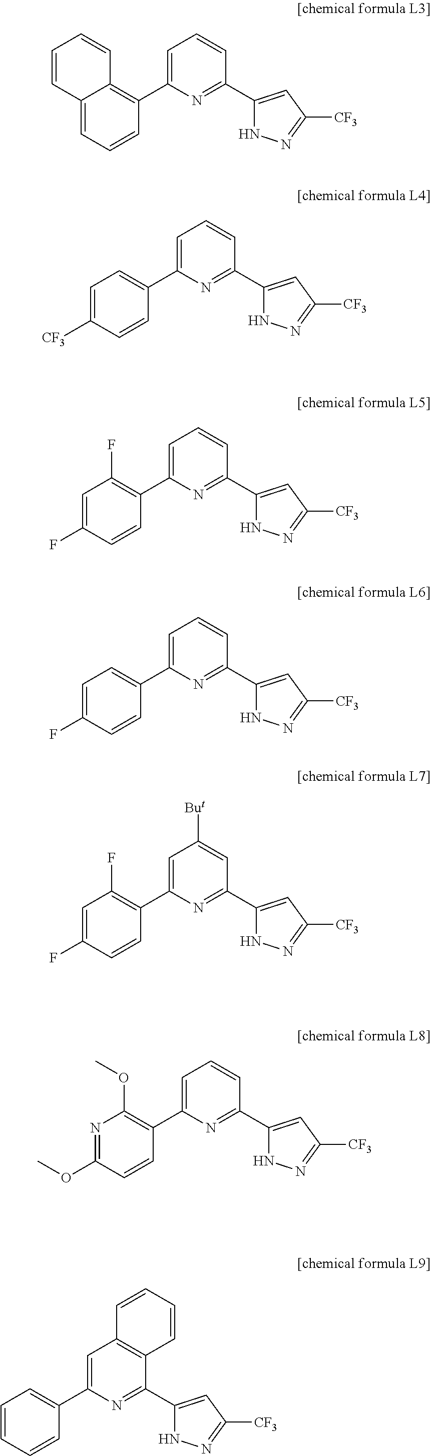

According to one embodiment of the iridium (III) based phosphor bearing pincer carbene and pyrazolyl chelates, wherein the iridium metal source complex is μ-chloro-bis[1,5-cyclooctadiene]iridium (III) dimer with the molecular formula of [Ir(COD)(μ-Cl)]₂.

### BRIEF DESCRIPTION OF THE DRAWINGS

The invention as well as a preferred mode of use and advantages thereof will be best understood by referring to the following detailed description of an illustrative embodiment in conjunction with the accompanying drawings.

### DETAILED DESCRIPTION OF THE PREFERRED EMBODIMENTS

To clearly describe iridium (III) based phosphor bearing both pincer carbene and pyrazolyl chelates according to the present invention, embodiments of the present invention will be described in detail with reference to the attached drawings hereinafter.

The present invention provides an iridium (III) based phosphor bearing both pincer carbene and pyrazolyl chelates, which can be applied as a guest light-emitting material in the OLED applications. The said iridium (III) based phosphor bearing both pincer carbene and pyrazolyl chelates is a novel phosphorescent Ir(III) metal complex, wherein this novel phosphorescent Ir(III) metal complex is synthesized using a dicarbene chelate, a pyrazolyl-based chelates and an iridium metal source complex as starting materials under the conditions specified in the experimental section.

Inheriting to above descriptions, the novel phosphorescent Ir(III) metal complex containing both the tridentate pincer carbene and pyrazolyl chelates is represented by following chemical formulas I, II, III, IV, V, VI, VII, VIII, and IX:

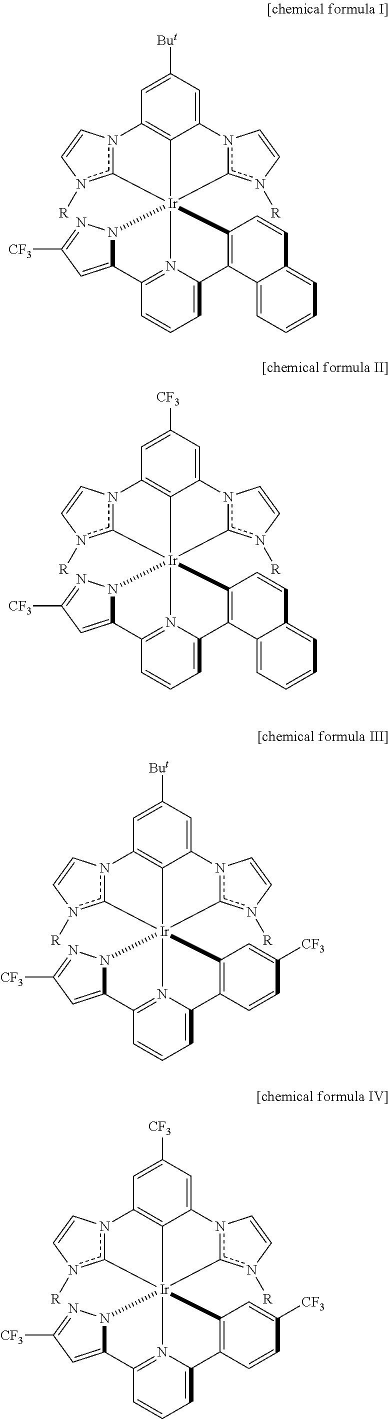

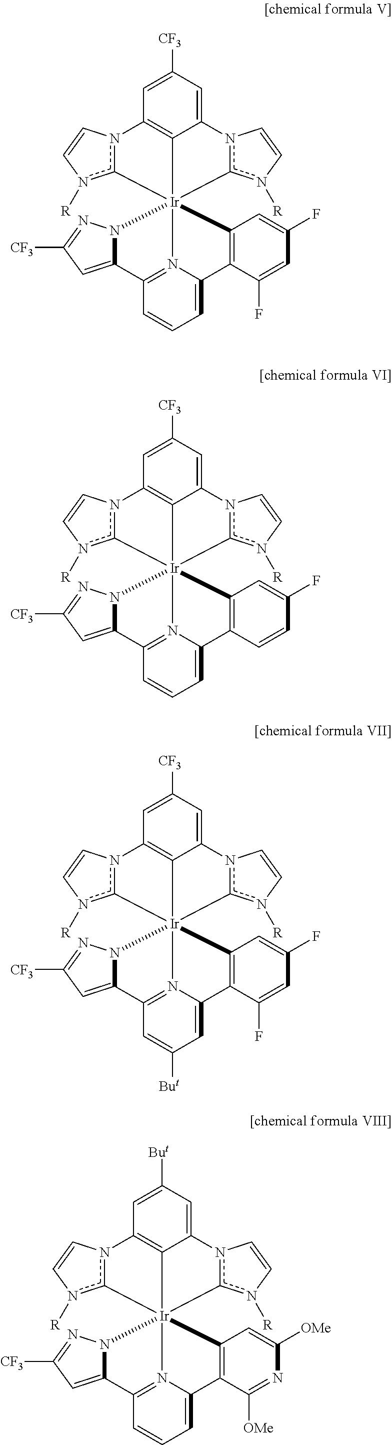

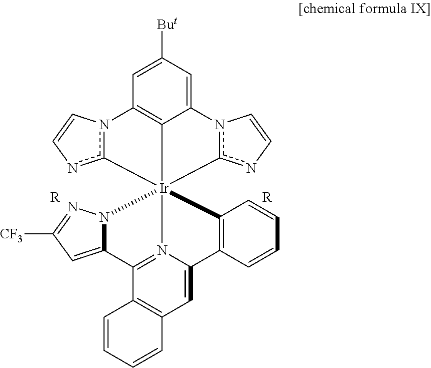

Moreover, the synthesis for the iridium (III) based phosphor bearing both pincer carbene and pyrazolyl chelates of the present invention consists the primary steps of:
(A) preparing a dicarbene chelate through chemical synthesis;
(B) synthesis of a pyrazolyl-based chelate through chemical synthesis;
(C) obtaining an iridium metal source complex; and
(D) taking the dicarbene chelate, the pyrazolyl-based chelate and the iridium metal source complex as starting materials for synthesis of the iridium (III) based phosphor bearing both pincer carbene and pyrazolyl chelates through chemical synthesis.

Continuously, a first synthetic method for the dicarbene chelate is proposed, which consists of following steps:
(S01) mixing 10 g of 1,3-dibromo-5-tert-butylbenzene (10 mmol), 1.7 g of imidazole (25 mmol), 5.5 g of K₂CO₃ (40 mmol), 0.08 g of Cu₂O (1 mmol), and 50 mL of DMSO (dimethyl sulfoxide) so as to obtain a mixture, and then stirring the mixture under 150° C. for 24 hours;
(S02) concentrating of the mixture obtained from the step (S01), so as to obtain a drude product;
(S03) preparing a silica gel column and eluting the crude product with organic solvent (CH₂Cl₂:MeOH=10:1, v/v) using column chromatographic technique, so as to obtain an intermediate product for the dicarbene chelate.

The intermediate product for the dicarbene chelate is represented by following chemical formula L1-1.

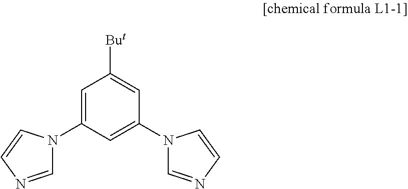

Moreover, it needs to further explain that, upon replacing 2.9 g of 1,3-dibromo-5-tert-butylbenzene (10 mmol) in the step (S01) with 3.0 g of 1,3-dibromo-5-trifluoromethylbenzene (10 mmol), the intermediate product of the following chemical formula L2-1 was obtained instead of the abovementioned chemical formula L1-1.

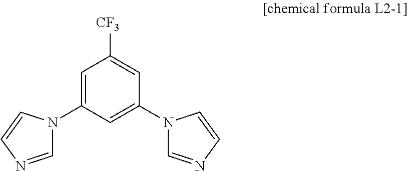 [SMILES: FC(F)(F)c1cc(-n2ccnc2)cc(-n2ccnc2)c1]

After finishing the synthesis of all intermediate products of the dicarbene chelates, a second synthetic procedure is executed for making the dicarbene chelate; wherein the second synthetic procedure consists of following steps:
(S01′) adding 2.7 g of intermediate product (10 mmol) and 17 g of 2-iodopropane (100 mmol) into 30 mL of acetonitrile, and then heating the acetonitrile solution at 100° C. for 24 hours in a nitrogen-filled environment;
(S02′) cooling the reaction mixture obtained from the step (S01′) down to room temperature, and filtering and concentrating the solution to obtain a white solid;
(S03′) dissolving the solid in 100 mL of water, and adding 16 g of ammonium hexafluorophosphate (100 mmol) into the water;
(S04′) filtering and then concentrating the aqueous solution obtained from the step (S03′), so as to obtain an end product of the dicarbene chelate.

The end product of the dicarbene chelate is represented by following chemical formula L1.

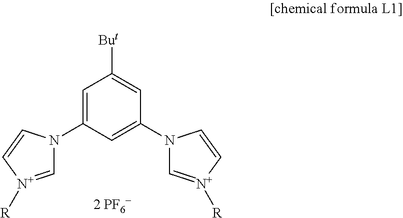

Herein, it is necessary to further explain that, upon replacing the (10 mmol, 2.7 g) intermediate product of chemical formula L1-1 in the step (S01′) with (10 mmol, 2.8 g) intermediate product of chemical formula L2-1, the intermediate product for the dicarbene chelate is then represented by following chemical formula L2 instead of abovementioned chemical formula L1.

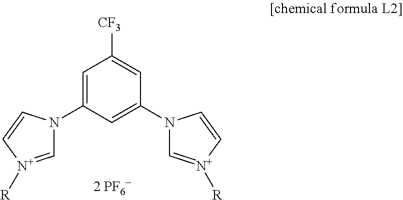

After finishing the fabrication of the dicarbene chelate, a third synthetic method for manufacturing the pyrazolyl-based chelate is continuously executed; wherein the third synthetic method consists of following steps:
(S01a) mixing the corresponding boric acid derivative with 2.0 g of 1-(6-bromopyridin-2-yl)ethanone (10 mmol), 1.4 g of Na₂CO₃ (10 mmol), 58 mg of Pd(PPh₃)₄ (0.05 mmol), and 100 mL of THF so as to obtain a mixture, and then stirring the mixture at 110° C. for 24 hours;
(S02a) concentrating the THF solution obtained from the step (S01a), so as to obtain a crude product;
(S03a) dissolving the crude product into ethyl acetate;
(S04a) filtering the solution obtained from the step (S03a) to obtain a filtrate;
(S05a) washing the filtrate with deionized water;
(S06a) removing the water in the filtrate obtained from the step (S05a) by treatment with Na₂SO₄, so as to obtain a crude product by concentrating the solution
(S07a) preparing a silica gel column and eluting the crude product with a mixed organic solvent (ethyl acetate:hexane=1:5, v/v) using column chromatography, so as to obtain an intermediate product for the pyrazolyl-based chelate.

Herein, it needs to note that, the intermediate product for the pyrazolyl-based chelate would be different according to the selected boric acid derivative; therefore, these intermediate products for the pyrazolyl-based chelates are represented by the following chemical formulas L3-1, L4-1, L5-1, L6-1, L7-1, L8-1, or L9-1.

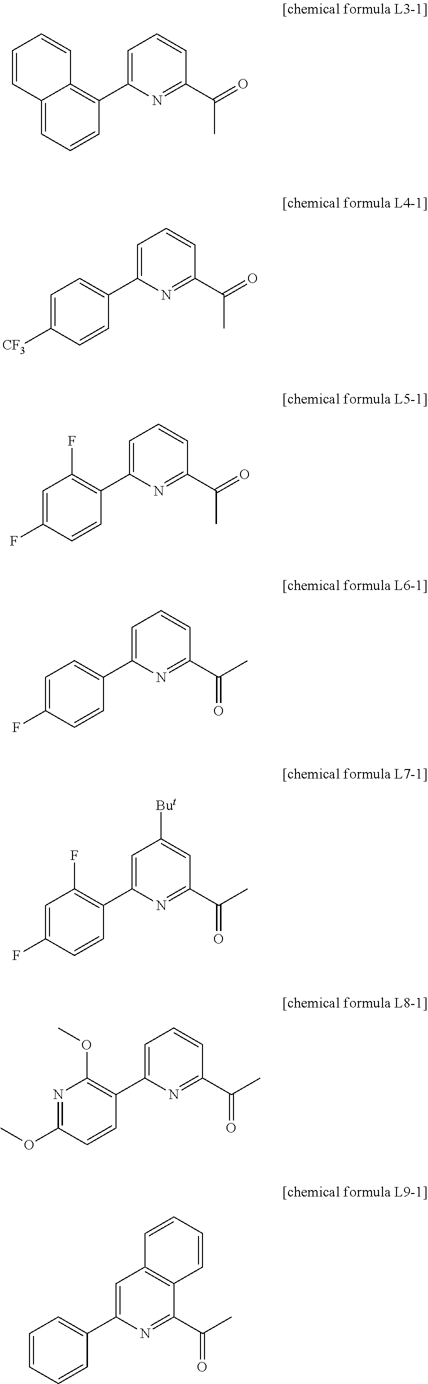

Herein, it is important to note that, although the synthetic method for L9-1 is different from the method demanded for L3-1˜L8-1, the technical engineers skilled in the art of organic synthesis should be able to find a proper method for synthesizing L9-1 by way of the synthetic method of L3-1˜L8-1, based on their own experience. For above reasons, the inventor of the present invention does not elaborate how to fabricate L9-1 anymore.

After obtaining intermediate product for the pyrazolyl-based chelate, a fourth synthetic method for manufacturing the pyrazolyl-based chelate is subsequently proposed; wherein the fourth synthetic method consists of following steps:
(S01a′) dissolving corresponding intermediate product (i.e., L3-1, L4-1, L5-1, L6-1, L7-1, L8-1, or L9-1) of the pyrazolyl-based chelate and 0.7 g of sodium ethoxide (NaOEt, 10 mmol) into THF;
(S02a′) dropping 1 4 mL of ethyl trifluoroacetate (10 mmol) into the mixture obtained from the step (S01a′);
(S03a′) stirring the mixture obtained from the step (S02a′) at 0° C. for 12 hours;
(S04a′) adding 2N HCl into the product obtained from the step (S03a′), so as to modulate the pH value of the mixture between 5 and 6;
(S05a′) extracting the mixture obtained from the step (SO4a′) three times using ethyl acetate as extracting solvent;
(S06a′) washing the extracted mixture obtained from the step (S05a′) by deionized water;
(S07a′) removing the water in the solution obtained from the step (S06a) by Na₂SO₄, so as to obtain an anhydrous solution;
(S08a′) concentrating the solution obtained from the step (S07a′), and then obtaining a crude product of 1,3-dione derivative;
(S09a′) dissolving the crude product of 1,3-dione derivative in 50 mL of ethanol;
(S10a′) adding 5 mL of hydrazine monohydrate (100 mmol) into the solution obtained from the step (S09a′), and then heating the solution under reflux for 24 hours;
(S11a′) cooling the solution obtained from the step (S10a′) down room temperature;
(S12a′) dissolving the crude product obtained from the step (S011a′) into ethyl acetate;
(S13a′) washing the ethyl acetate solution obtained from the step (S13a′) by deionized water;
(S14a′) drying the solution obtained from the step (S13a′) by Na₂SO₄, followed by concentrating the solution to dryness so as to obtain a crude product;
(S15a′) preparing a silica gel column and eluting the crude product by a mixed organic solvent (ethyl acetate:hexane=1:3, v/v) using column chromatography, so as to obtain an end product for the pyrazolyl-based chelate.
The end product for the pyrazolyl-based chelate is represented by following chemical formulas L3, L4, L5, L6, L7, L8, or L9.

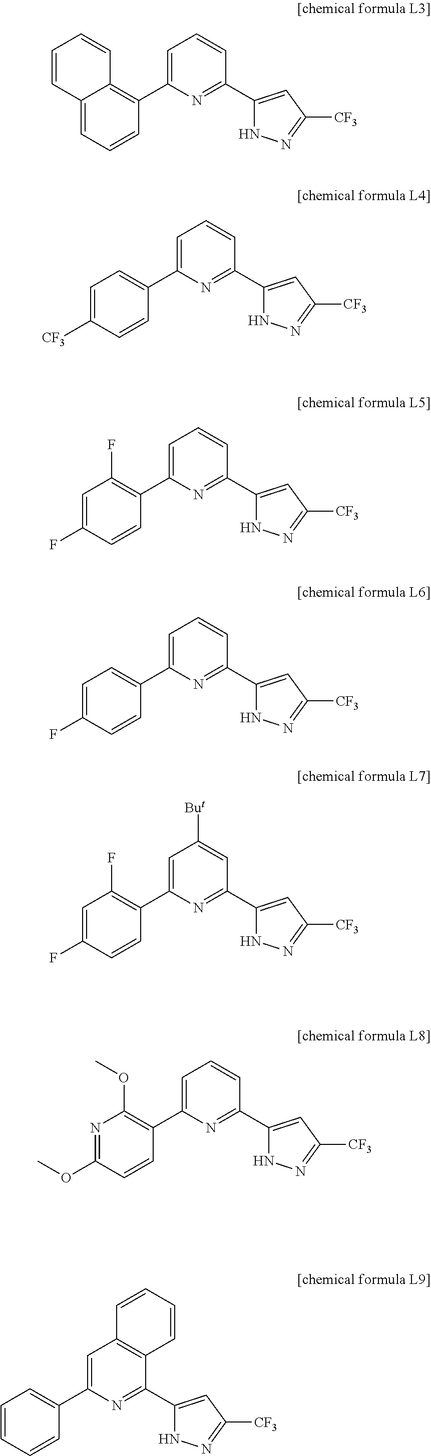

Continuously, a fifth method for synthesizing the novel phosphorescent Ir(III) metal complex containing double tridentate ligands, wherein the fifth method consists of the following steps:
(S01b) adding the dicarbene chelate of L1 or L2, the iridium metal source complex, and 336 mg of sodium acetate (NaOAc, 4 mmol) into 100 mL of acetonitrile (CH₃CN); wherein the said iridium metal source complex is μ-chloro-bis[1,5-cyclooctadiene] iridium (III) dimer with the molecular formula of [Ir(COD)(μ-Cl)]₂;
(S02b) heating the mixture obtained from the step (S01b) at 100° C. for 12 hours under a nitrogen atmosphere;
(S03b) removing the volatile solvent of the mixture obtained from the step (S02b);
(S04b) adding corresponding pyrazolyl-based chelate (i.e., L3, L4, L5, L6, L7, L8, or L9) and 100 mL of xylenes into the reaction mixture obtained from the step (S03b);
(S05b) heating the mixture obtained from the step (S04b) at 140° C. for 12 hours;
(S06b) cooling the product mixture obtained from the step (S05b) down to room temperature; after then, the solvent in the product mixture is completely removed, such that a crude product for the novel phosphorescent Ir(III) metal complex is obtained;
(S07b) preparing a silica gel column and eluting the crude product with a mixed organic solvent (ethyl acetate:hexane=1:3, v/v) using chromatography technique, so as to obtain the purified product of the novel phosphorescent Ir(III) metal complex.

The related photophyscial data of the embodiments for the phosphorescent Ir(III) metal complex containing double tridentate ligands are recorded and compiled in Table 1. In this table, the abbreviation abs λₘₐₓ stands for the absorption peak wavelength of an ultraviolet-visible absorption spectrum, while PL λₘₐₓ exhibits the emission peak wavelength recorded in the photoluminescence spectrum. In additio, the Greek letters τ and Φ indicate the emission lifetime and quantum yield of the phosphorescent Ir(III) metal complex containing the double tridentate ligands. Therefore, from Table 1, it is able to know that both embodiments 5 and 6 are the excellent emissive materials suitable for fabrication of blue phosphorescent organic light emitting diodes with high luminescence efficiency.

TABLE 1

| | abs λₘₐₓ | PL λₘₐₓ | | |
|---|---|---|---|---|
| Embodiments | (nm) | (nm) | τ (μs) | Φ (%) |
| Embodiment 1 | 282, 314, | 622 | 5.91 | 13.5 |
| (chemical | 416, 465 | | | |
| formula I) | | | | |
| Embodiment 2 | 293, 331, | 623 | 7.69 | 11.6 |
| (chemical | 428, 453 | | | |
| formula II) | | | | |
| Embodiment 3 | 289, 307, | 503, 537, | 2.98 | 78.6 |
| (chemical | 326, 493 | 583, 638 | | |
| formula III) | | | | |
| Embodiment 4 | 290, 325, | 493, 530, | 4.88 | 93.0 |
| (chemical | 408, 486 | 568, 622 | | |
| formula IV) | | | | |
| Embodiment 5 | 296, 323, | 464, 495, | 4.52 | 90.0 |
| (chemical | 406, 456 | 529, 577 | | |
| formula V) | | | | |
| Embodiment 6 | 281, 326, | 469, 502, | 6.38 | 87.4 |
| (chemical | 408, 435 | 533, 581 | | |
| formula VI) | | | | |
| Embodiment 7 | 277, 324, | 464, 496, | 4.67 | 75.9 |
| (chemical | 398, 440 | 528, 582 | | |
| formula VII) | | | | |
| Embodiment 8 | 305, 371 | 465, 494, | 6.21 | 57.8 |
| (chemical | | 526, 577 | | |
| formula VIII) | | | | |
| Embodiment 9 | 326, 367, | 595 | 6.88 | 98 |
| (chemical | 416, 457 | | | |
| formula IX) | | | | |

Furthermore, the energy level of HOMO and gap of HOMO/LUMO orbital, i.e. E_{HOMO} and E_{gap}, for these phosphorescent Ir(III) metal complex are also recorded and compiled in Table 2.

TABLE 2

| Embodiments | E_{HOMO} (eV) | E_{gap} (eV) |
|---|---|---|
| Embodiment 1 | 5.17, 5.49 | 2.32 |
| (chemical | | |
| formula I) | | |
| Embodiment 2 | 5.33, 5.63 | 2.32 |
| (chemical | | |
| formula II) | | |
| Embodiment 3 | 5.23, 5.57 | 2.60 |
| (chemical | | |
| formula III) | | |
| Embodiment 4 | 5.51, 5.87 | 2.63 |
| (chemical | | |
| formula IV) | | |
| Embodiment 5 | 5.53, 5.90 | 2.79 |
| (chemical | | |
| formula V) | | |
| Embodiment 6 | 5.48, 5.83 | 2.76 |
| (chemical | | |
| formula VI) | | |
| Embodiment 7 | 5.48 | 2.81 |
| (chemical | | |
| formula VII) | | |
| Embodiment 8 | 5.26, 5.55 | 2.82 |
| (chemical | | |
| formula VIII) | | |
| Embodiment 9 | 4.93 | 2.19 |
| (chemical | | |
| formula IX) | | |

From chemical formulas I˜IX, Table 1 and Table 2, it is able to find that, the luminescence color of the iridium (III) based phosphor bearing both pincer carbene and pyrazolyl chelates proposed by the present invention can be modulated by proper adjustment of their associated energy levels, i.e. E_{HOMO} and E_{gap}, and molecular structure. For example, the embodiment 3 (i.e., chemical formula III) is fabricated by using the dicarbene chelate of chemical formula L1, the pyrazolyl-based chelate of chemical formula L4 as the starting materials. Besides, the embodiment 4 (i.e., chemical formula IV) is fabricated by using the dicarbene chelate of chemical formula L2, the pyrazolyl-based chelate of chemical formula L4 as the starting materials. As showed in Table 1, the photoluminescence peak wavelength of embodiment 3 and embodiment 4 are recorded to be 503 nm and 493 nm, respectively. That is, the phosphorescent emission of embodiment 3 is red-shifted (i.e. with a slightly lower energy) compared to that of embodiment 4 under the same condition.

Accordingly, the person skilled in the art of optoelectronic material can easily understand that the E_{HOMO} level (highest occupied molecular orbital energy level of host, HOMO) of embodiment 4 is decreased by the electron-withdrawing group of CF₃, and that is the reason for embodiment 4's energy gap (E_{gap}) being greater than that of embodiment 3. Therefore, the emission peak wavelength of embodiment 4 is found to be more blue-shifted compared with that of embodiment 3.

Of course, among this class of proposed phosphorescent Ir(III) metal complex containing double tridentate ligands, the demanded variation of luminescence color (molecular energy level) can be modulated by variation of the pyrazolyl-based chelate. For instance, the embodiment 4 (i.e., chemical formula IV) is fabricated by using the dicarbene chelate of chemical formula L2 and the pyrazolyl-based chelate of chemical formula L4 as the starting materials. Besides, the embodiment 5 (i.e., chemical formula V) is fabricated by using the dicarbene chelate of chemical formula L2 and the pyrazolyl-based chelate of chemical formula L5 as the starting materials. Moreover, as showed in Table 1, the first emission peak wavelength of embodiment 4 and embodiment 5 are located at 493 nm and 464 nm, respectively. That is, the embodiment 4 has a lower emission energy gap versus embodiment 5, while its phosphorescence is more red-shifted compared to that of the embodiment 5.

It is well known that the electronegativity of fluoro group is higher than others functional group. As a result, the person skilled in the art of molecular material can easily understand that the E_{HOMO} level of embodiment 5 is lowered by the high electronegativity provided by the two fluoro groups. Hence, this explains the greater energy gap (E_{gap}) of embodiment 5 versus that of embodiment 4. Therefore, embodiment 5 possesses larger energy gap versus embodiment 4, and the emission color is further blue-shifted as recorded.

Through abovementioned discussion and step-by-step delineation of their optoelectronic behaviors, the systematic variation of iridium (III) based phosphor bearing both pincer carbene and pyrazolyl chelates proposed by the present invention have been clearly explained; in summary, the present invention includes the following advantages:
(1) Differing from the conventional cyclometalated Ir(III) metal complexes, this class of novel phosphorescent Ir(III) metal complex is synthesized from a class of pincer carbene derivative, a class of pyrazolyl-based chelate and an iridium metal source complex. Because the phosphorescent Ir(III) metal complex proposed by the present invention includes several strong coordination bonds (Ir—C bond), the non-radiative decay from the higher lying triplet excited state can be effectively suppressed. Thus, this novel class of phosphorescent Ir(III) metal complex is able to emit a range of visible light (particularly the blue light) with high color purity and high efficiency as neat sample. Moreover, this novel phosphorescent Ir(III) metal complex is also capable to adapt as a guest emitter in the light emitting layer (EML) for the traditional doped OLED architecture.
(2) Moreover, the experimental data of embodiments 1˜9 have proved that, through proper selection of dicarbene chelate and/or pyrazolyl-based chelate, the luminescence color of the iridium (III) based phosphor bearing both pincer carbene and pyrazolyl chelates proposed by the present invention can be modulated by adjusting the corresponding energy level of HOMO and HOMO/LUMO energy gaps.

The above description is made on embodiments of the present invention. However, the embodiments are not intended to limit scope of the present invention, and all equivalent implementations or alterations within the spirit of the present invention still fall within the scope of the present invention.

What is claimed is:

1. An iridium (III) based phosphor bearing both pincer carbene and pyrazolyl chelates, and fabricated by using a dicarbene chelate, a pyrazolyl-based chelate and an iridium metal source complex as starting materials for carrying out chemical synthesis.

2. The iridium (III) based phosphor bearing both pincer carbene and pyrazolyl chelates of claim 1, wherein the phosphorescent Ir(III) metal complex is represented by following chemical formulas I, II, III, IV, V, VI, VII, VIII, and IX: 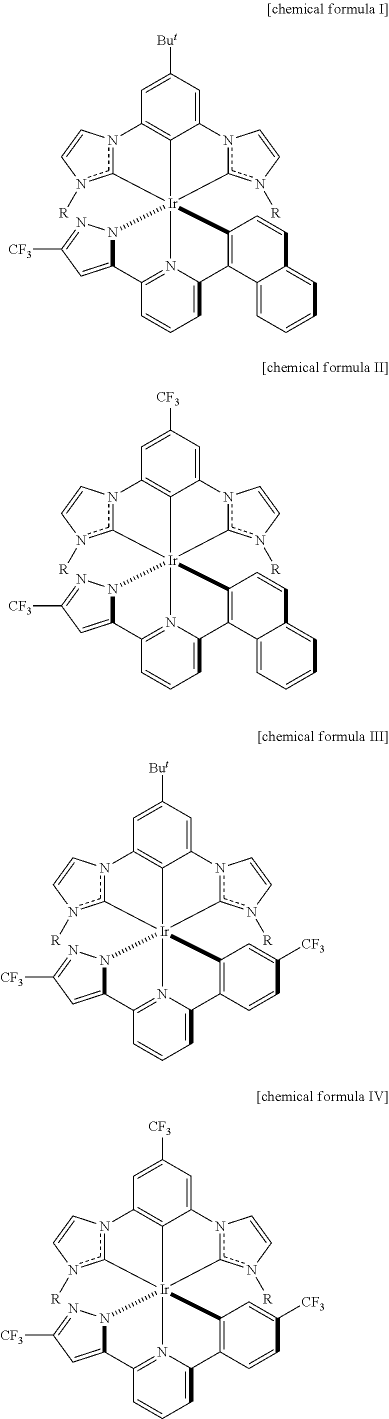 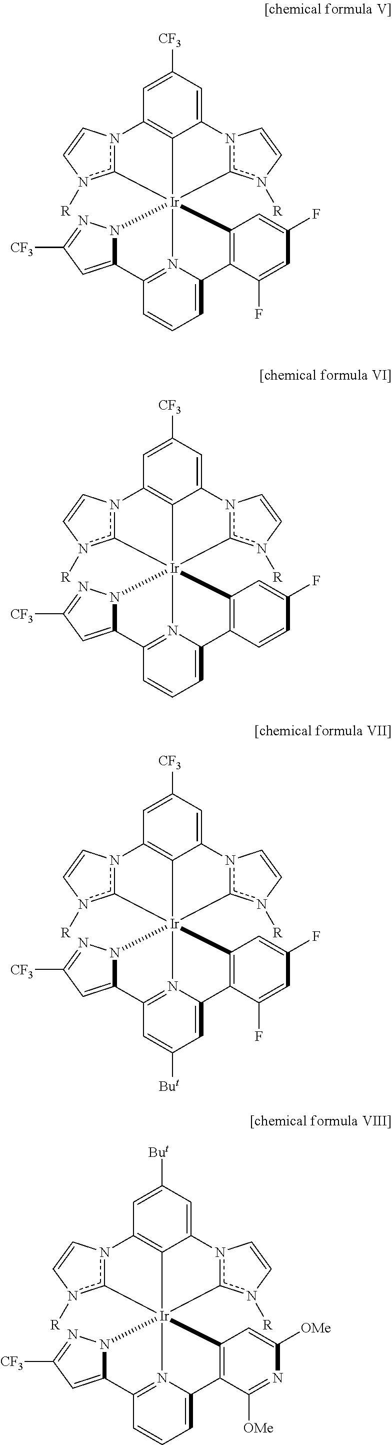 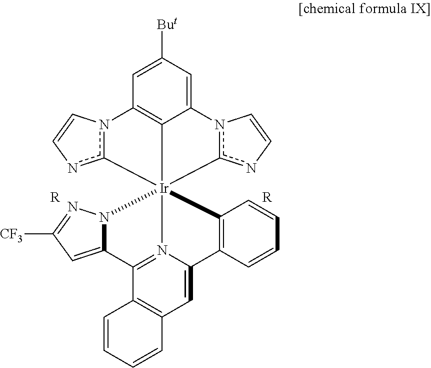
wherein R in chemical formulas I˜IX is an aliphatic substituent represented by isopropyl (i-Pr).

3. The iridium (III) based phosphor bearing both pincer carbene and pyrazolyl chelates of claim 1, wherein the dicarbene chelate is synthesized from following chemical formulas L1 and L2: 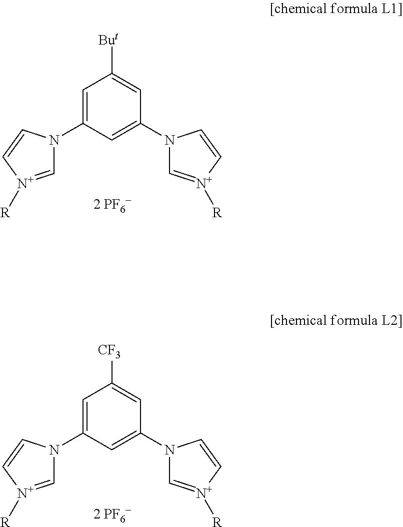
wherein R in chemical formulas L1 and L2 is an aliphatic molecular group represented by isopropyl (i-Pr).

4. The iridium (III) based phosphor bearing pincer carbene and pyrazolyl chelates of claim 1, wherein the pyrazolyl-based chelate is synthesized from the following chemical formulas L3, L4, L5, L6, L7, L8, and L9:

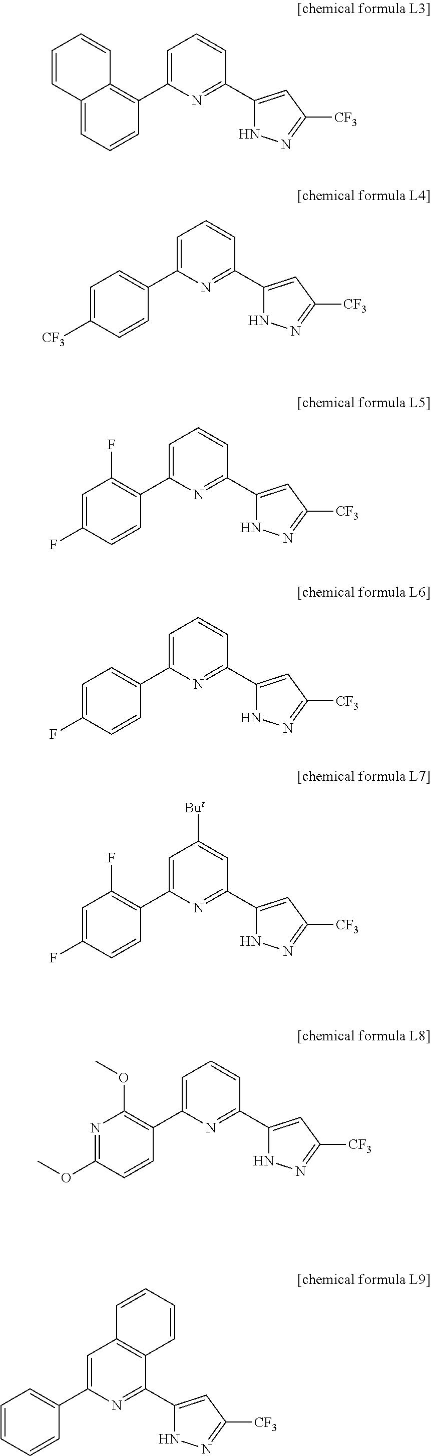

5. The iridium (III) based phosphor bearing both pincer carbene and pyrazolyl chelates of claim 1, wherein the iridium metal source complex is μ-chloro-bis[1,5-cyclooctadiene]iridium (III) dimer with the molecular formula of [Ir(COD)(μ-Cl)]₂.

6. The iridium (III) based phosphor bearing both pincer carbene and pyrazolyl chelates of claim 1, having highest occupied molecular orbital energy levels (E_{HOMO}) ranged from 5.1 eV to 5.65 eV.

7. The iridium (III) based phosphor bearing both pincer carbene and pyrazolyl chelates of claim 1, wherein the phosphorescent Ir(III) metal complex containing double tridentate ligands can be applied as a guest light-emitting material in the OLED applications.
